(19) United States
(12) Patent Application Publication
(10) Pub. No.: US 2005/0104215 A1
(43) Pub. Date: May 19, 2005

(54) Barrier layers for tin-bearing solder joints

(76) Inventors: Cheng-Heng Kao, Taoyuan (TW); Wan-Chun Chang, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,042

(22) Filed: Jun. 15, 2004

(30) Foreign Application Priority Data
Nov. 13, 2003 (TW) 92131755

(51) Int. Cl. H01L 23/48

(52) U.S. Cl. 257/751

(57) ABSTRACT

A contact structure is suitable for contacting with a soldering bump. The contact structure mainly comprises a bonding pad and an under bump metallurgy including a platinum barrier layer. The platinum barrier layer is disposed between the bonding pad and the soldering bump. The platinum barrier layer with the lower consumption rate and oxidation resistance capability can be used instead of the conventional nickel barrier layer.

### CROSS REFERENCE TO RELATED APPLICATIONS

This application claims the priority benefit of Taiwan application serial no. 92131755, filed on Nov. 13, 2003.

### BACKGROUND OF INVENTION

1. Field of the Invention

This invention relates in general to a contact structure, and more specifically relates to a contact structure having the oxidation resistance capability with a lower consumption rate.

2. Description of Related Art

The electronic products have become everyday goods in the information society era. The core components of the electronic products are chips. The chip is packaged in a manner to electrically connect to external circuits. A flip chip package can be used for connecting the chip with the substrate. The substrate is connected to a printed circuit board by soldering. There are many bonding pads on the chips, the substrate and the printed circuit board. Therefore, the property of the soldering bump and the soldering property between the bonding pads of the electronic device and the soldering bumps are very important for the long service life of a electronic product.

FIG. 1 schematically shows a cross-sectional view of a contact structure and a soldering bump in a conventional flip chip structure. In general, the flip chip structure 10 comprises a chip 100, a plurality of contact structures 110 and a plurality of soldering bumps 130. In FIG. 1, only one contact structure and one soldering bump are depicted for simplicity. The contact structure 110 is arranged above the chip 100, and comprises a bonding pad 112 and an under bump metallurgy 120. The bonding pad 112 can be a copper-bonding pad for example, and is arranged on an active surface of the chip 100. The under bump metallurgy 120 is disposed between the bonding pad 112 and the soldering bump 130 to increase adhesion between the bonding pad 112 and the soldering bump 130. The material of the soldering bump 130 usually uses a tin-contained soldering bump that has a better soldering property.

The under bump metallurgy 120 comprises an adhesion layer 122, a barrier layer 124 and an oxidation protection layer 126. The adhesion layer 122 is disposed on the bonding pad 112 for increasing the adhesion strength between the bonding pad 112 and the barrier layer 124. The material of the adhesion layer 122 can be a titanium metal. The barrier layer 124 is disposed on the adhesion layer 122 for blocking a diffusion phenomenon of the soldering bump 130, and can be made of nickel metal for example. The oxidation protection layer 126 is disposed on the barrier layer 124 for preventing the contact structure 110 from being oxidized. The material of the oxidation protection layer 126 is gold or palladium.

Presently, nickel metal is a material of choice for the barrier layer 124. The nickel metal can react with tin in the soldering bump 130 to retard tin from diffusing downwards, and thereby achieving a barrier effect.

As described above, at the beginning stage of soldering, metal atoms in the oxidation protection layer (i.e., the gold metal) 126 will enter the interior of the tin-containing soldering bump 130 at a very high speed, and therefore, a gold-containing compound is formed in the soldering bump 130. After the oxidation layer (the gold layer) 126 is completely consumed or disappears, the barrier layer (i.e., the nickel layer) 124 comes in contact with the tin-containing soldering bump 130 and form a nickel-containing compound. Since the formation of the nickel-containing compound will cause the consumption of the barrier layer (the nickel layer) 124, the copper-bonding pad 112 quickly reacts with the copper-soldering bump 120 due to the loss of the barrier layer 124 when the barrier layer 124 is completely consumed. Therefore, after losing the blockade of the nickel layer 124, it can be expected that the copper-bonding pad 112 is consumed by the soldering bump 130 at a very high speed. If the copper-bonding pad 112 is further consumed, the connection between the soldering bump 120 and the chip 100 becomes very fragile and an open loop will occur. Therefore, there is a demand for a metal barrier layer with a powerful retardation capability to block the diffusion, i.e., with a consumption rate lower than the nickel layer.

### SUMMARY OF INVENTION

According to the foregoing description, this invention is related to a contact structure in which the conventional nickel barrier layer is replaced with a platinum barrier layer for increasing the capability of retarding the diffusion. In this way, the tin-contained soldering bump can be prevented from quickly reacting with the bonding pad, therefore the reliability of packaging of electronic devices can be increased.

This invention is also directed to a contact structure in which the conventional nickel barrier layer is replaced with a platinum barrier layer. The platinum barrier layer can be also used to serve as the oxidation protection layer. Therefore, the manufacturing process can be simplified and the cost can be reduced.

In one embodiment of the present invention, the contact structure further comprises a wetting layer disposed between the platinum barrier layer and the soldering bump for increasing a wetting effect between the platinum barrier layer and the soldering bump. The wetting layer can be composed of gold.

In one embodiment of the present invention, the contact structure further comprises an adhesion layer disposed between the bonding pad and the platinum barrier layer for increasing an adhesion strength. The adhesion layer can be composed of titanium.

In one embodiment of the present invention, the platinum barrier layer is formed by an electroplating process, an evaporation process, an electroless plating process or a sputtering process.

In one embodiment of the present invention, the bonding pad is a copper bonding pad or an aluminum bonding pad. The contact structure can be disposed on a chip, a chip carrier, or a printed circuit board.

According to an aspect of the present invention, the nickel metal is replaced by the platinum metal in the barrier layer. Since the consumption rate of the platinum is lower than that of the nickel, therefore the platinum containing barrier layer can effectively reduce the diffusion reaction of the tin-containing bonding pad and thereby provide a better barrier effect. Therefore, the reliability of the packaging of electric devices can be increased. In addition, the platinum metal itself has the oxidation resistance capability, and therefore, the platinum metal layer can serve both as oxidation protection layer as well as the barrier layer. As a result, the manufacturing process can be simplified and the cost can be also reduced.

### BRIEF DESCRIPTION OF DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings.

FIG. 1 schematically shows a cross-sectional view of a contact structure and a soldering bump in a conventional flip chip structure.

FIG. 2 shows a schematic cross-sectional view of a contact structure and a soldering bump in a flip chip structure according to one embodiment of the present invention.

FIG. 3 shows a relationship between consumed thickness and reaction time of the nickel and the platinum at 250° C.

FIG. 4 shows a relationship between consumed thickness and reaction temperature of the nickel and the platinum at different temperatures for one hour.

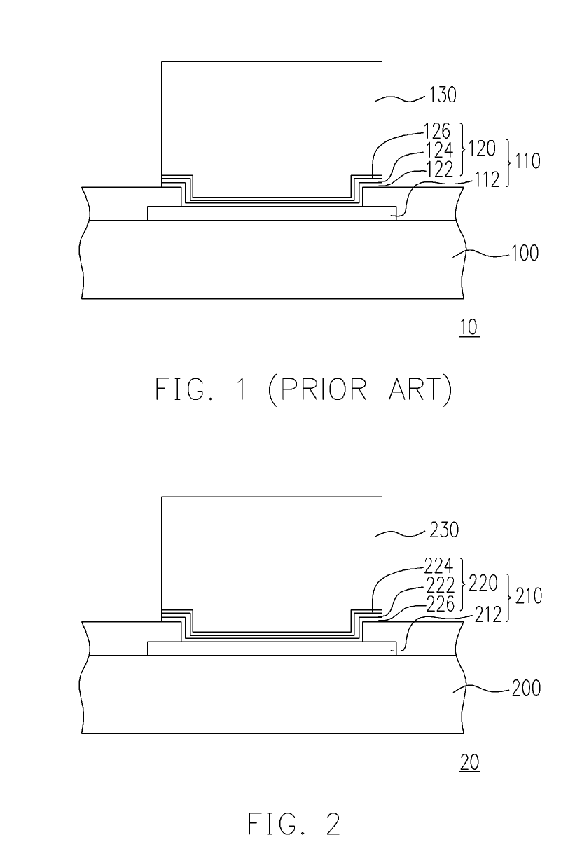

### DETAILED DESCRIPTION

FIG. 2 shows a schematic cross-sectional view of a contact structure and a soldering bump in a flip chip structure according to one embodiment of the present invention. The flip chip structure 20 is mainly constructed by a chip 200, a plurality of contact structures 210 and a plurality of soldering bumps 230. In FIG. 2, only one contact structure 210 and one soldering bump 230 are depicted for simplicity. The contact structure 210 is arranged above the chip 200, and comprises a bonding pad 212 and an under bump metallurgy 220. The bonding pad 212 can be a copper bonding pad or an aluminum-bonding pad for example, and is arranged on an active surface of the chip 200. The under bump metallurgy 220 is disposed between the bonding pad 212 and the soldering bump 230 for increasing adhesion. The material of the soldering bump 230 usually comprises a tin-containing soldering bump.

Referring to FIG. 2, the under bump metallurgy 220 comprises a platinum barrier layer 222. The platinum barrier layer 222 formed between the bonding pad 212 and the soldering bump 230 can be also used as the oxidation protection layer. The barrier-oxidation protection layer 222 can be formed via an electroplating process, an evaporation process, an electroless plating process or a sputtering process. In order to increase the wetting effect between the platinum barrier layer 222 and the soldering bump 230, a wetting layer 224 is selectively disposed between the platinum barrier layer 222 and the soldering bump 230. The wetting layer 224 can be composed of gold. Furthermore, an adhesion layer 226 can be selectively disposed between the bonding pad 212 and the platinum barrier layer 222 for increasing adhesion strength. The adhesion layer 226 can be composed of titanium.

According to one feature of the present invention, the conventional nickel barrier layer is replaced with the platinum metal layer. The relative consumption rates of nickel and platinum reacting with the tin-contained solder are provided below to prove that the platinum has a better barrier capability.

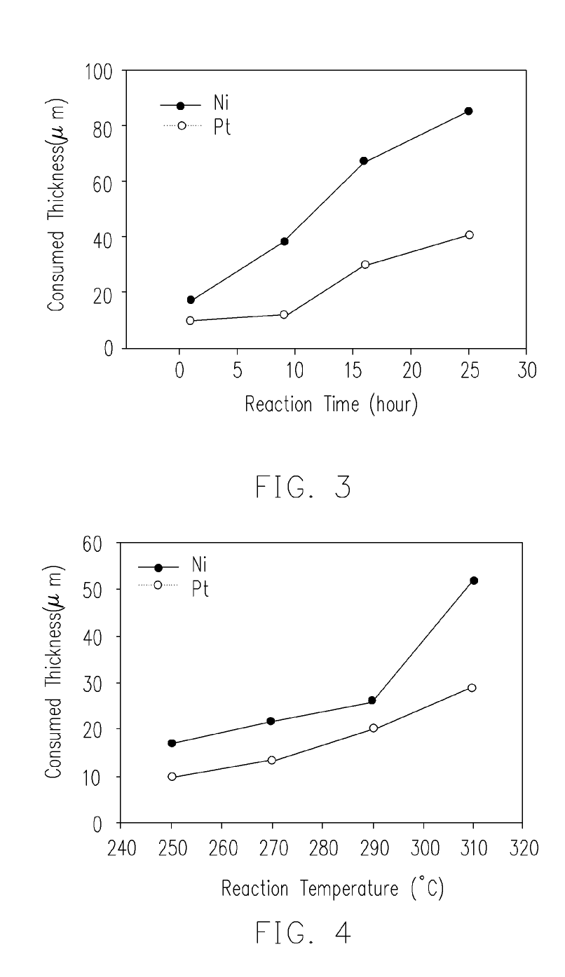

FIG. 3 shows a relationship between consumed thickness and reaction time of nickel and platinum at 250° C. FIG. 4 shows a relationship between consumed thickness and reaction temperature of nickel and platinum metals at different temperatures for one hour. In FIG. 3, as the reaction times of the nickel and the platinum with the tin increases, at 250° C., the consumed thickness of nickel is always larger than that of the platinum. Therefore, for the reaction rate at 250° C., the platinum is a better material compared to nickel for serving as a barrier layer. FIG. 4 shows a comparison of consumed thickness of platinum and nickel respectively reacting with tin for one hour at different temperatures. As shown in FIG. 4, the consumed thickness of the nickel is always larger than that of the platinum at any temperature. Therefore, for the reaction rate at any temperature, platinum is a better material than nickel for serving as a barrier layer.

In addition, the wetting effects of nickel and platinum with the tin solder are similar. Therefore, the nickel and the platinum have the similar wetting capability.

Since the platinum is a noble metal, and thus the platinum itself has an oxidation resistance capability. Therefore, in addition to serving as the barrier layer, platinum can be also used as an oxidation protection layer.

As described above, according to an embodiment of the present invention, nickel metal is replaced with platinum metal in the barrier layer. Since the consumption rate of platinum is lower than that of nickel, platinum can effectively reduce the diffusion reaction of the tin-contained bonding pad and provide a better barrier effect. Therefore, the reliability of packaging of the electric devices can be increased. In addition, the platinum metal itself has oxidation resistance capability, and therefore, platinum metal layer can serve both as oxidation protection layer as well as barrier layer. As a result, the manufacturing process can be simplified and the cost can be also reduced.

In the above embodiment, the contact structure having a platinum-containing metal layer is used in the flip chip package. However, those skilled in this art would understand that the present invention is not limited to the contact structure having the platinum-containing metal layer of disposed on the chip, the contact structure of the present invention can be also applied to a chip carrier or a surface finish layer of a printed circuit board.

In summary, according to the present invention, the platinum is used as the barrier layer, and the consumption rate of the platinum barrier layer is substantially lower than the conventional nickel barrier layer. Therefore, the diffusion reaction of the tin-contained bonding pad can be reduced and a better barrier effect can be achieved, so that the reliability of packaging of the electric devices can be increased.

Furthermore, according to an embodiment of the present invention, the platinum is adapted for serving as the barrier layer and the platinum itself being resistant to oxidation, and therefore the platinum barrier layer can also used as the oxidation protection layer for preventing the formation of native oxide on the surface of the contact structure. Therefore, no additional step for forming the oxidation layer as in the case of the conventional art is required, and thus the cost and the manufacturing time can be reduced.

While the present invention has been described with a preferred embodiment, this description is not intended to limit our invention. Various modifications of the embodiment will be apparent to those skilled in the art. It is therefore contemplated that the appended claims will cover any such modifications or embodiments as fall within the true scope of the invention.

1. A contact structure, for connecting with a soldering bump, the contact structure comprising:
a bonding pad; and
an under bump metallurgy, comprising a platinum barrier layer disposed between the soldering bump and the bonding pad, wherein the soldering bump contains tin.

2. The contact structure of claim 1, wherein the under bump metallurgy further comprises a wetting layer disposed between the platinum barrier layer and the soldering bump.

3. The contact structure of claim 2, wherein the wetting layer comprises gold.

4. The contact structure of claim 1, wherein the under bump metallurgy further comprises an adhesion layer disposed between the bonding pad and the platinum barrier layer.

5. The contact structure of claim 4, wherein the adhesion layer comprises titanium.

6. The contact structure of claim 1, wherein the platinum barrier layer is formed by an electroplating process, an evaporation process, an electroless plating process or an sputtering process.

7. The contact structure of claim 1, wherein the bonding pad is a copper bonding pad or an aluminum bonding pad.

8. The contact structure of claim 1, wherein the contact structure is disposed on a chip.

9. The contact structure of claim 1, wherein the contact structure is disposed on a chip carrier.

10. The contact structure of claim 1, wherein the contact structure is disposed on a printed circuit board.

11. An under bump metallurgy for connecting with a tin soldering bump, the under bump metallurgy comprising:
a wetting layer in contact with the tin solder bump;
a adhesion layer; and
a platinum barrier layer, disposed between the wetting layer and the adhesion layer.

12. The under bump metallurgy of claim 11, wherein the wetting layer comprises gold.

13. The under bump metallurgy of claim 11, wherein the adhesion layer comprises titanium.

14. A conductive structure, comprising:
a bonding pad;
an adhesion layer, disposed over the bonding pad;
a platinum barrier layer, disposed over the adhesion layer;
a wetting layer, disposed over the platinum barrier layer; and
a tin-contained metal structure, disposed over the wetting layer.

15. The conductive structure of claim 14, wherein the wetting layer comprises gold.

16. The conductive structure of claim 14, wherein the adhesion layer comprises titanium.

17. The conductive structure of claim 14, wherein the tin-contained metal structure is a tin-containing soldering bump.

18. The conductive structure of claim 14, wherein the bonding pad is a copper bonding pad or an aluminum bonding pad.

19. The conductive structure of claim 14, wherein the conductive structure is disposed on a chip, a chip carrier or a printed circuit board.
